(19) United States
(12) Patent Application Publication
(10) Pub. No.: US 2018/0092227 A1
(43) Pub. Date: Mar. 29, 2018

(54) EQUIPMENT RACK SUPPORT AND STABILIZATION SYSTEM

(71) Applicant: SCHNEIDER ELECTRIC IT CORPORATION, West Kingston, RI (US)

(72) Inventors: William P. Stewart, St. Peters, MO (US); Kenneth Schaller, O'Fallon, MO (US)

(21) Appl. No.: 15/277,513

(22) Filed: Sep. 27, 2016

(51) Int. Cl. H05K 5/02; H05K 7/20

(52) U.S. Cl. CPC H05K 5/0204; H05K 7/20545

(57) ABSTRACT

An equipment rack support and stabilization system configured to support electronic equipment and related accessories is disclosed. Such a system may include a plurality of retention brackets, each retention bracket having a first plate and a second plate extending from the first plate, the first plate having one or more openings formed therein. A plurality of channel spacers, each channel spacer having a lower tier, an upper tier, and a tier interconnect, the lower tier of the channel spacer being configured to connect and support the second plate of the retention bracket. A plurality of rack floor panels, each rack floor panel having a top, a bottom, and a plurality of retention slots, the top of each rack floor panel being configured to support the equipment rack, and the second plate of the retention bracket being configured to fit within a retention slot of the plurality of retention slots. A plurality of aisle floor panels connected to and supported by the upper tiers of the plurality of channel spacers.

### BACKGROUND

### Field of the Invention

Embodiments of the present disclosure relate generally to racks and rack enclosures, and more specifically to support and stabilization systems for racks and rack enclosures, which support electronic equipment and related accessories.

### Description of the Related Art

Racks and modular rack systems are generally used to receive and store electronic equipment and accessories to that equipment. Traditional equipment manufacturers may provide such racks in four post-modular rack systems (e.g. a rack cabinet) or two post racks. For a large amount of electronic equipment, these traditional rack and modular rack systems may be placed adjacent to each other for the advantages of thermal airflow management, space conservation, security, or limiting a run of cables that may occur between racks to connect equipment housed in adjacent racks.

Physical support for electronic equipment may be accomplished by directly attaching the equipment to the rack or modular rack system. Alternatively, mounting equipment rails or shelves attached to the rack or modular rack system may also be used to support equipment. Equipment may generally be mounted in any orientation that the physical configuration of the equipment and modular rack system permits. Examples of such equipment which may be mounted include, computers, printed circuit assemblies, power or data distribution devices, cable management devices, doorways, or other associated accessories.

Safe storage and operation of the equipment requires support or stabilization of the rack and rack systems. Generally, drilling into a floor and securing the rack or rack system through the use of anchors is a typical, and permanent solution. Other less secure solutions may include not anchoring the rack or rack system, and relying on the mass of any installed equipment to prevent the rack or rack enclosure from moving or tipping. These solutions are unsafe, particularly in an environment which may experience seismic activity, and do not allow for robust or rapid reconfiguration or repositioning the rack or rack system as is typical and often necessary in today's dynamic data center operations.

### SUMMARY

An equipment rack support and stabilization system configured to support electronic equipment and related accessories is disclosed. An equipment rack support and stabilization system may include more than one retention bracket, each retention bracket having a first plate and a second plate that extends from the first plate. One or more openings are formed in the first plate of the retention bracket and are used to secure to the equipment rack. More than one channel spacer may also be included, each channel spacer having a lower tier, an upper tier, and a tier interconnect. The lower tier of the channel spacer connects and supports the second plate of each retention bracket. Further, more than one rack floor panel may also be included, each rack floor panel having a top, a bottom, and more than one retention slot. The top of each rack floor panel supports at least a portion of the equipment rack and the second plate of the retention bracket fits within the retention slot of each rack floor panel. More than one aisle floor panel may also be included, with each aisle floor panel being connected to and supported by the upper tier of each channel spacer.

Principles of the disclosure provide a retention bracket configured with a first plate and a second plate, consisting of a top second plate, a bottom second plate, and a second plate slot. The first plate is configured approximately perpendicular to the second plate and rotated approximately perpendicular on a horizontal axis. The top second plate is operatively connected on one side of the bottom of the first plate.

Principles of the disclosure provide the equipment rack support and stabilization system where the one or more openings disposed within the first plate of each retention bracket may accept a fastener to releasably secure the equipment rack. A rack base mounting plate to secure the equipment rack to the first plate of the plurality of retention brackets may be included. Also, one or more of the openings disposed within the rack base mounting plate may accept a fastener to releasably secure the equipment rack. Each retention bracket may allow the adjustment of the first plate or the second plate, which may be extended and retracted to achieve a height.

Principles of the disclosure also contemplate the rack floor panel and/or the aisle floor panel may be perforated to allow airflow between the top and the bottom of the floor panel in either direction. Further, the rack and/or aisle floor panel may contain an integrated channel spacer and/or retention bracket.

Principles of the disclosure also contemplate a kit for a rack support and stabilization system. Such a kit may include one or more retention brackets, each retention bracket having a first plate and a second plate. One or more openings are formed in the first plate of the retention bracket and are used to secure to an equipment rack. The kit further includes one or more channel spacers, each channel spacer having a lower tier, an upper tier, and a tier interconnect. The lower tiers of the channel spacers operatively connect and support the second plates of the retention brackets. The kit further includes one or more rack floor panels, each floor panel having a top, a bottom, and a plurality of retention slots. The tops of the plurality of rack floor panels support the equipment rack, and the second plates of the retention brackets fit within the plurality of retention slots. Such a kit may also include one or more rack base mounting plates to secure the equipment rack and the first plate of the plurality of retention brackets and/or one or more aisle floor panels connected to and supported by the upper tiers of the channel spacers.

Principles of the disclosure also contemplate a method for installing an equipment rack support and stabilization system which includes, installing a plurality of channel spacers on a floor, each channel spacer having an upper tier and a lower tier; installing second plates of a plurality of retention brackets to the lower tiers of the plurality of channel spacers; installing a plurality of rack floor panels between the plurality of channel spacers such that the plurality of retention slots is aligned with a first plate of the plurality of retention brackets; installing a plurality of aisle floor panels, each aisle floor panel having a top and a bottom. The bottom of each aisle floor panel is operatively connected to the upper tier of the channel spacer and the second plate of the retention bracket; and installing an equipment rack supported by the tops of the plurality of rack floor panels and the first plates of the plurality of retention brackets.

### BRIEF DESCRIPTION OF THE DRAWINGS

These accompanying drawings are not intended to be drawn to scale. In the drawings, each identical or nearly identical component that is illustrated in various figures is represented by a line numeral. For purposes of clarity, not every component may be labeled in every drawing. In the drawings:

FIG. 1 illustrates aspects of a system for supporting and stabilizing an equipment rack in accordance with various embodiment of this disclosure;

FIG. 2 illustrates an enlarged perspective view of a system for supporting and stabilizing an equipment rack in accordance with various embodiment of this disclosure;

FIG. 3A illustrates a perspective view of a retention bracket component of a system for supporting and stabilizing an equipment rack in accordance with various embodiments of this disclosure;

FIG. 3B illustrates an alternate embodiment of a retention bracket component of a system for supporting and stabilizing an equipment rack in accordance with various embodiments of this disclosure;

FIG. 3C illustrates an alternate embodiment of a retention bracket component of a system for supporting and stabilizing an equipment rack in accordance with various embodiments of this disclosure;

FIG. 4 illustrates a perspective view of a channel spacer component of a system for supporting and stabilizing an equipment rack in accordance with various embodiments of this disclosure;

FIG. 5A illustrates a top view of a rack floor panel component of a system for supporting and stabilizing an equipment rack in accordance with various embodiments of this disclosure;

FIG. 5B illustrates a perspective view of a rack floor panel component of a system for supporting and stabilizing an equipment rack in accordance with various embodiments of this disclosure;

FIG. 6A illustrates a perspective view of an alternate embodiment for supporting and stabilizing an equipment rack in accordance with various embodiments of this disclosure;

FIG. 6B illustrates a perspective view of an alternate embodiment for supporting and stabilizing an equipment rack in accordance with various embodiments of this disclosure;

FIG. 7 illustrates an exploded perspective view of an alternate embodiment for supporting and stabilizing an equipment rack in accordance with various embodiments of this disclosure;

FIG. 8A illustrates a perspective view of an alternate embodiment of a combined floor panel for supporting and stabilizing an equipment rack in accordance with various embodiments of this disclosure;

FIG. 8B illustrates a cross sectional view of the combined floor panel of FIG. 8A;

FIG. 8C illustrates a cross sectional view of an alternate embodiment of the combined floor panel of FIG. 8A;

FIG. 9A illustrates a perspective view of an alternate embodiment of a rack floor panel adaptor for supporting and stabilizing an equipment rack in accordance with various embodiments of this disclosure; and

FIG. 9B illustrates a cross sectional view of alternate embodiment of the rack floor panel adaptor illustrated in FIG. 9A.

### DETAILED DESCRIPTION

This invention is not limited in its application to the details of construction and the arrangement of components set forth in the following descriptions or illustrated by the drawings. The invention is capable of other embodiments and of being practiced or of being carried out in various ways. Also, the phraseology and terminology used herein is for the purpose of descriptions and should not be regarded as limiting. The use of “including,” “comprising,” “having,” “containing,” “involving,” and variations herein, are meant to be open-ended, i.e. “including but not limited to.”

Data centers may be designed to house a large number and type of electronic equipment. Examples of such equipment may include data processing, storage, and networking equipment. When housed, such equipment generally resides within equipment racks of various construction or modular rack systems. Each equipment rack or modular rack system may be configured to include an open frame consisting of two or four posts. A four-post rack may also be enclosed on each side, top, and/or bottom. For air containment, privacy, and/or security each individual rack may include side panels, a ceiling, and/or a roof. One or more doors may also replace a panel so as to readily enable access into the interior of the equipment rack.

Such equipment racks are generally monolithic in construction where the basic structure of the rack or rack enclosure may not be configured to be modified easily or in any way. Some racks may be rolled into and out of position on pre-assembled wheel assemblies and these wheels “locked” into place, while other equipment racks are bolted to the floor and/or walls of the structure itself, others still may be assembled from component parts in situ. Once the equipment rack or modular rack system is secured, electronic equipment or accessories may be positioned within the equipment rack without creating an additional hazard such as tipping.

Today, equipment racks are used in a variety of applications and locations. Facilities which house such equipment racks may be traditional “brick and mortar” buildings, temporary structures, or mobile enclosures such as containerized data centers. Such equipment racks may be installed on an “as needed basis” or “on demand” basis, and the type, manufacturer, and location of the equipment rack may not be predefined, and indeed change over time in an effort to support the particular function and available and changing manufacturers of such equipment.

In many of these applications, a secure attachment between the rack or rack system and the floor is required to meet the service needs of the customer, established standards, and/or governmental regulations and/or guidelines (FEMA P-749 as one of many examples). Such a solution is often a bracket system attached to the bottom cross member of the equipment rack and then fastened directly to a floor with anchors or additional fasteners to secure the enclosure in place.

Many existing solutions generally include multiple equipment racks stored at a single location such as a data center. In such a scenario, to gain access for moving a single rack, it is likely multiple racks must be moved. Further, the existing process of securing a rack or rack enclosure generally requires creating holes in the floor and the use of brackets for each equipment rack or a common bracket used for several equipment racks. As a result, substantial reconfiguration generally in the form of removing and replacing several anchoring devices from the desired and adjacent racks, is required to reposition a single equipment rack.

Further, such a static solution generally does not allow other configurable applications that are likely to arise over time due to variability in equipment such as rack width. Also, such existing solutions requires the destruction of portions of the facility which houses the racks or rack systems. This generally takes the form of drilling anchors into the floor, walls, and/or ceilings. Finally, such mounting hardware is generally obtrusive and a tripping hazard for individuals in the vicinity of the equipment racks as the anchors or hardware to secure the anchors often resides above the floor in the aisle designed for individuals.

At least one embodiment of the present disclosure is directed to an equipment rack support and stabilization system configured to support electronic equipment and related accessories. An equipment rack support and stabilization system includes an equipment rack, more than one retention bracket, each retention bracket having a vertical plate and a horizontal plate with respect to the equipment rack. One or more openings are formed in the vertical plate of the retention bracket and are used to secure to the equipment rack. More than one channel spacer may also be included, each channel spacer having a lower tier, an upper tier, and a tier interconnect. The lower tier of the channel spacer connects and supports the horizontal plates of the retention brackets. Further, more than one rack floor panel has a top, a bottom, and more than one retention slots. The top of each rack floor panel at least partially supports the equipment rack, and the horizontal plate of the retention bracket fits within its respective retention slot of each rack floor panel. More than one aisle floor panel may also be included, and is connected to and supported by the upper tier of each of the channel spacers.

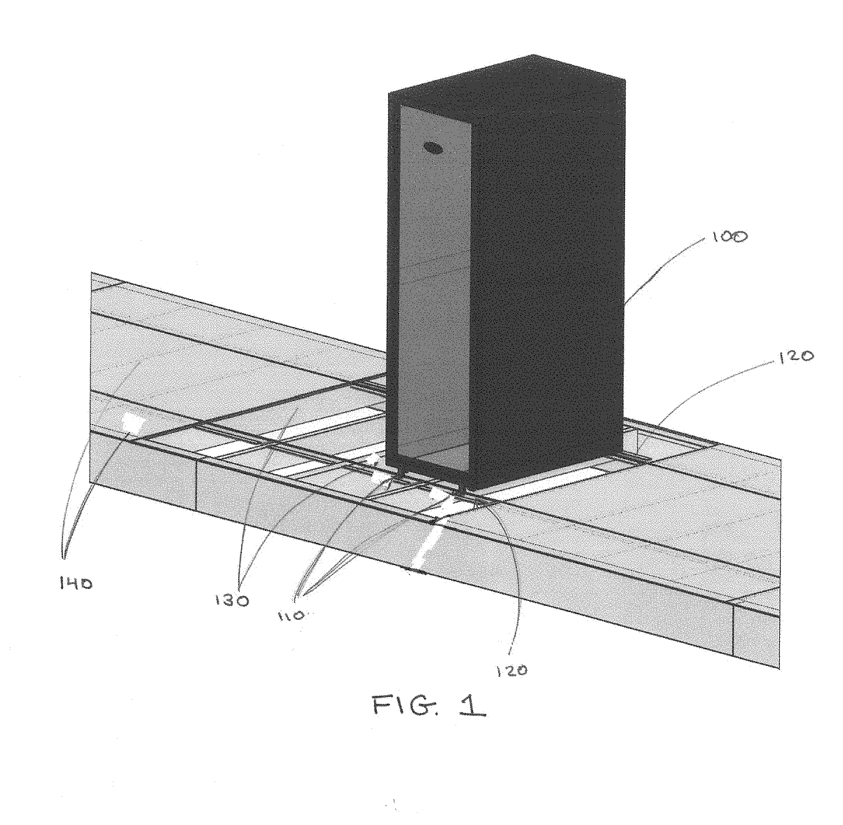

Referring now to FIG. 1, aspects of a system for supporting and stabilizing an equipment rack, such as equipment rack 100, in accordance with various embodiments of this disclosure are illustrated. Components of embodiments of this system include a plurality of retention brackets, each indicated at 110, a plurality of channel spacers, each indicated at 120, a plurality of rack floor panels, each indicated at 130, and a plurality of aisle floor panels, each indicated at 140. It should be appreciated while one equipment rack 100 is illustrated, embodiments of the disclosure contemplate multiple racks of various physical dimensions from any source.

The equipment rack 100 may be any device configured for the storage of equipment for a particular application such as, but not limited to, electronic equipment for use in a data center. The equipment rack 100 may be configured as an open frame consisting of two or four posts. A four-post equipment rack may also be enclosed on each side, top, and bottom. A door may also replace one or more panels to readily enable access into the interior of the equipment rack. For air containment, privacy, and/or security each individual rack may include side panels, a ceiling, and a roof.

Assemblies of two post racks, four post racks, open frame, enclosed, or any combination of rails, bars, hooks, pegs, or other components configured to receive electronic equipment are contemplated in this disclosure. Such equipment racks may be monolithic in construction where the basic structure of the rack or rack enclosure may or may not be modified. Some may be configured to be rolled into and out of position on pre-assembled wheel assemblies and these wheels “locked” into place, while other equipment racks are bolted to the floor and/or walls of the structure containing the equipment racks 100 itself. Equipment racks 100 may also be built in situ. Composition of an equipment rack 100 may be materials, such as, but not limited to steel, aluminum, or other materials which provide mechanical support of any installed equipment.

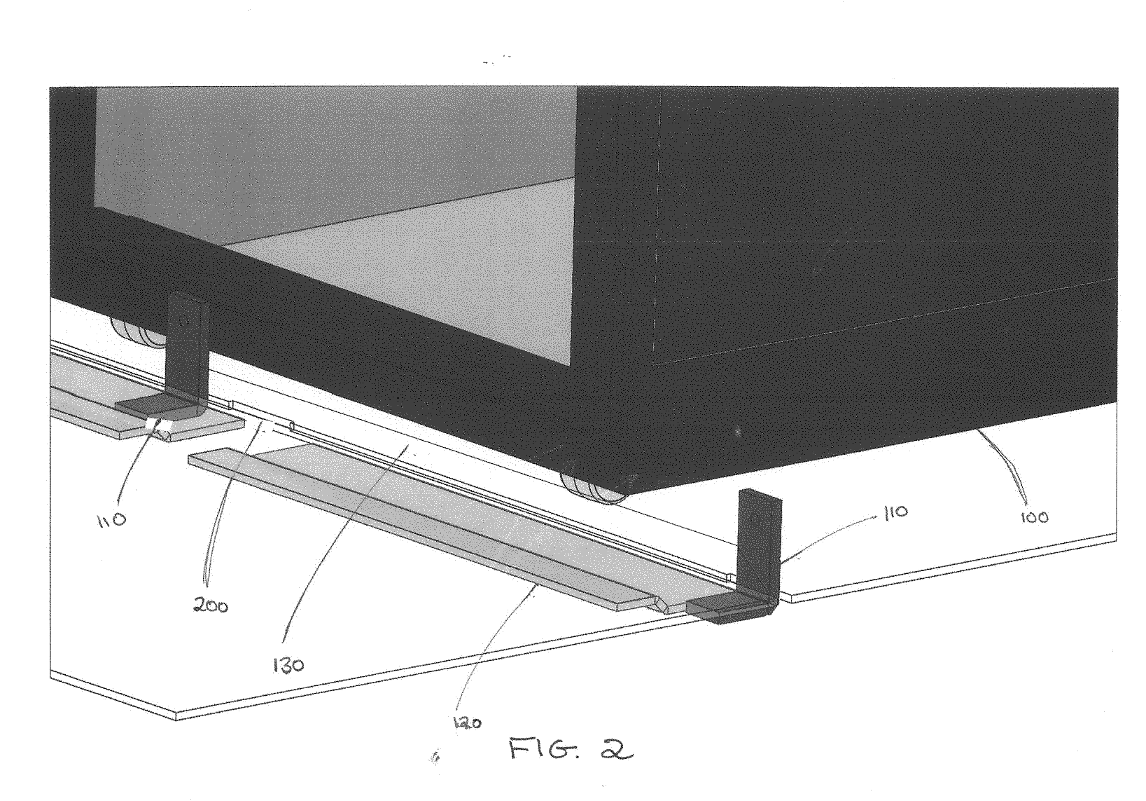

FIG. 2 illustrates an enlarged perspective view of the system for supporting and stabilizing an equipment rack in accordance with various embodiment of this disclosure. The equipment rack 100 is supported by the rack floor panel 130. Each rack floor panel 130 contains a plurality of retention slots 200, which allow the channel spacer 120 to operatively connect the rack floor panel 130 with the channel spacer 120 utilizing the retention slots 200. Each channel spacer 120 also operatively connects to an aisle floor panel 140. It should be appreciated while FIG. 2 illustrates embodiments of the disclosure, many other embodiments are possible utilizing the detailed components. Of particular import is a wide array of equipment rack 100 types are contemplated in this disclosure.

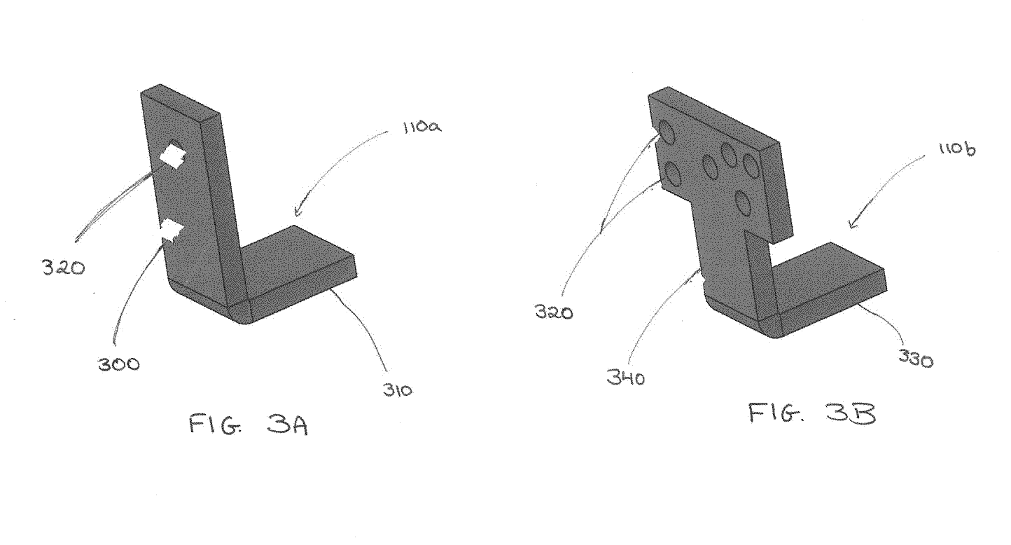

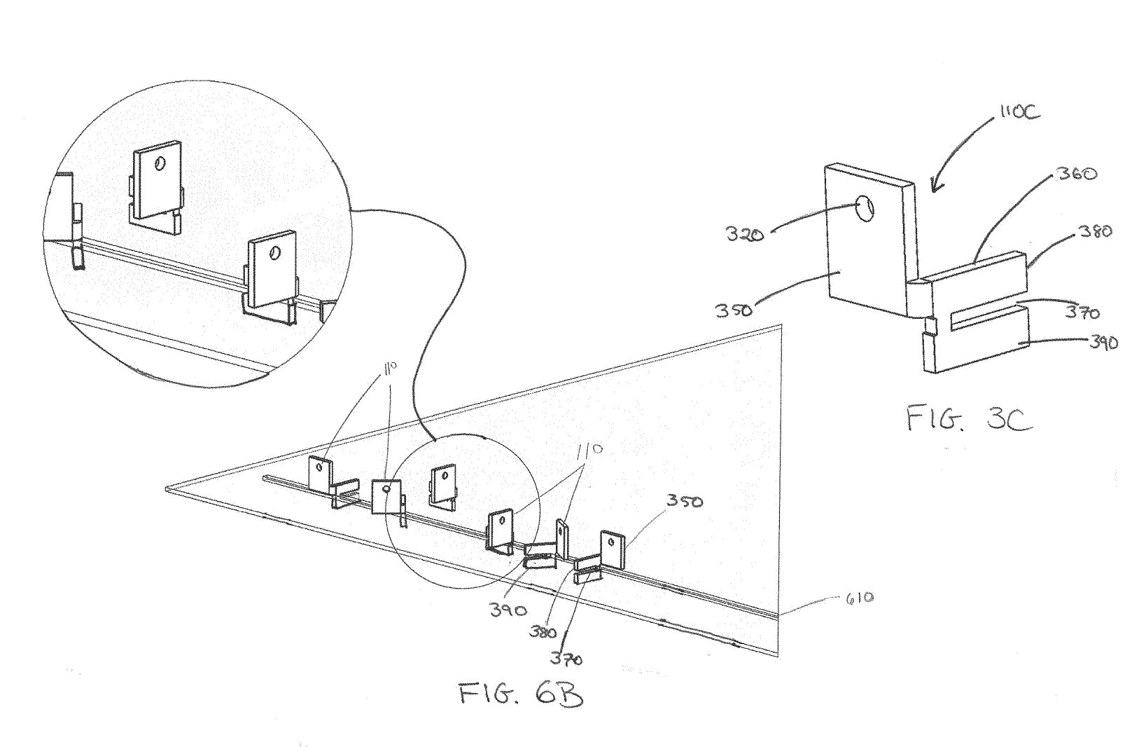

FIG. 3A illustrates a perspective view of the retention bracket 110a of the system for supporting and stabilizing an equipment rack in accordance with various embodiments described herein. In this embodiment, the retention bracket 110a has a vertical (first) plate 300 and a horizontal (second) plate 310 (as oriented in FIG. 3A), which are formed approximately perpendicular from each other in a generally “L” bracket configuration. Other angular formations are contemplated in this disclosure, and may be used based on the application. While a roughly rectangular shape is illustrated for both the vertical plate 300 and the horizontal plate 310, the basic shape of each plate may be any shape, such as, but not limited to square, rectangle, triangle, or circular, which provides adequate support for the equipment rack 100 and channel spacer 120 when connected. One or more openings 320 are formed in the vertical plate 300 of the retention bracket 110a to secure to the equipment rack 100. While one opening 320 is illustrated in FIG. 3A, variation in both number and location in the vertical plate 300 are contemplated to support a variety of interface points and associated hardware in operatively connecting the equipment rack 100.

FIG. 3B illustrates an alternate embodiment of the retention bracket 110b. In the illustrated embodiment, the retention bracket 110b has a vertical (first) plate 340 and a horizontal (second) plate 330 (as oriented in FIG. 3B), which are formed approximately perpendicular from each other in a generally “L” bracket configuration. Other angular formations are contemplated in this disclosure, and may be used based on the application. In this embodiment, the vertical plate 340 is configured to have a wider top portion extending laterally from a central portion of the vertical plate 340, and is configured to provide additional surface area for contact with the equipment rack 100. A plurality of openings, each indicated at 320, are formed in the vertical plate 340 of the retention bracket 110b to operatively connect the retention bracket 110b to the equipment rack 100. While a T-shaped structure is illustrated for the vertical plate 340, including the top portion, and the horizontal plate 330, the basic shape may be any shape that provides adequate support for the equipment rack 100 and channel spacer 120 when connected.

FIG. 3C illustrates a further alternate embodiment of the retention bracket 110c. Each retention bracket 110c has a vertical plate 350 and a horizontal plate 360 (as oriented in FIG. 3C). The horizontal plate 360 includes a top horizontal plate 380, a bottom horizontal plate 390, and a horizontal plate slot 370 positioned between the top horizontal plate 380 and the bottom horizontal plate 390. In this embodiment, the vertical plate 350 is configured approximately perpendicular to the horizontal plate 360 and rotated approximately perpendicular on a horizontal axis in which the top horizontal plate 380 is operatively connected on one side of the bottom of the vertical plate 350. It should be appreciated that other angular formations are contemplated in this disclosure, and may be used based on the application. While one opening 320 is illustrated, variation in both number and location in the vertical plate 350 are contemplated to support a variety of interface points and associated hardware in operatively connecting the equipment rack 100.

It should be appreciated for various embodiments, the openings 320 disposed on the vertical plate of the retention bracket 110 may be of any shape such as, but not limited to, round, square, triangular, oval, or any other shape to accommodate connecting hardware. Further, smooth or threaded openings 320 are contemplated to accommodate a variety of hardware such as spring pins, bolts, or any other hardware to operatively connect the retention bracket 110 to the equipment rack 100. A wide array of opening 320 patterns is contemplated in this disclosure to allow for an operative connection to a wide array of equipment racks 100. Embodiments of the disclosure also contemplate that the retention bracket 110 allows the vertical plate 300, 340, 350 to be adjustable to achieve a height and the horizontal plate 310, 330, 360, 380, 390 to achieve a depth. As one possible example, a slot and pin assembly may be disposed on the vertical and/or horizontal plate to provide a mechanism for adjustments. Both or neither plates may be adjustable and may be a fixed height or depth respectively.

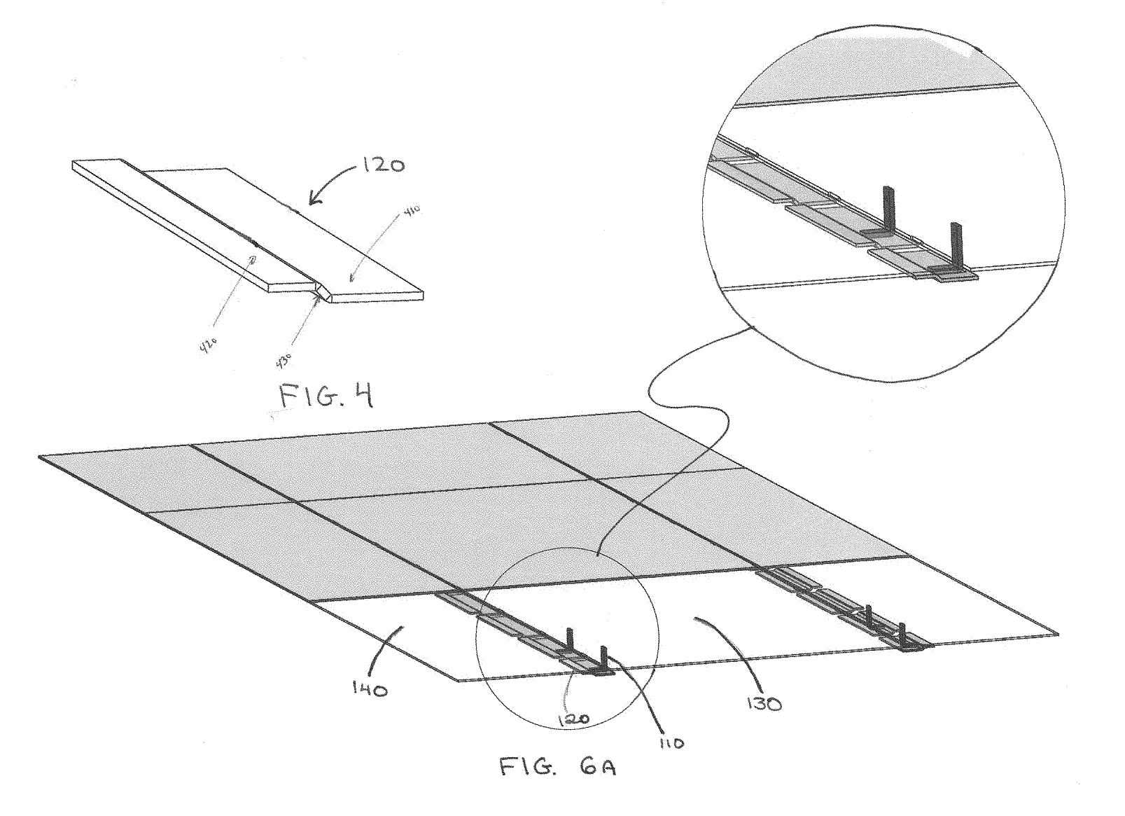

FIG. 4 illustrates a perspective view of the channel spacer 120 of the system for supporting and stabilizing an equipment rack in accordance with various embodiments of this disclosure. Each channel 120 spacer has a lower tier 410, an upper tier 420, and a tier interconnect 430. The lower tiers of the channel spacers operatively connect and support the horizontal plates 310, 330, 380, 390 of the retention brackets 110. Both the lower tier 410 and upper tier 420 are approximately parallel to each other, and are connected by the tier interconnect 430. The tier interconnect 430 may be formed at any angle to allow a separation of the lower tier 410 and upper tier 420. While a particular angle is illustrated within the disclosure, embodiments contemplate various embodiments, including, but not limited to right, straight, acute, and obtuse angles.

To allow for the necessary support of the other components of the system, the channel spacer 120 may be formed from a single piece of material or from multiple assembled parts of the same or various dimensions to accommodate various rack and rack system geometries. Further, the channel spacer 120 may be fabricated to be adjustable and set by a user for any variety of configurations.

It should be appreciated that materials used in construction of embodiments of the retention brackets 110, the channel spacers 120, the rack floor panels 130, and the aisle floor panels 140 are various. For example, plastic, steel, carbon fiber, or other materials are able to be used, provided the material is suitable to support the structural load. Further, any combination of embodiments may be used in a single system. Implementations are not limited to any one embodiment nor limited by the embodiment chosen.

FIG. 5A illustrates a top view of the rack floor panel 130 of the system for supporting and stabilizing an equipment rack in accordance with various embodiments of this disclosure. FIG. 5B illustrates a perspective view of FIG. 5A. Each rack floor panel 130 has a top 510, a bottom, and one or more retention slots, each indicated at 520. Each rack floor panel 130 may be configured to support the equipment rack 100. However, if no equipment rack 100 is present, the rack floor panel 130 may be configured to operate as a generic floor tile.

Each rack floor panel 130 has one or more retention slots 520 disposed within the edges of the rack floor panel 130. Each retention slot 520 extends the full depth of the rack floor panel 130 and operatively connects the vertical plate 300, 340, 350 of the retention bracket 110. A preferred embodiment will contemplate the dimensions of each retention slot 520 to be of the approximate dimensions of the vertical plate 300, 340, 350 of the retention bracket 110 such that the retention bracket 110 fits substantially flush into the retention slot 520.

Retention slots 520 may be disposed on any edge and in any pattern on the retention bracket 110. FIG. 5A and FIG. 5B illustrate one preferred embodiment with the retention slots 520 on opposite edges of the rack floor tile 130. Various embodiments are contemplated in this disclosure, including but not limited to, retention slots 520 on none, or any combination of sides of the rack floor panel 130. Further, while a particular number of disposed retention slots 520 are illustrated, none, or any number are contemplated as part of this disclosure. At a minimum, the width of each retention slot 520 must be configured to operatively connect each retention bracket 110.

Each rack floor panel 130 and each aisle floor panel 140 may be configured to support a mechanical load or to contain and direct conditioned or not conditioned air within the subject enclosure. Each type of floor panel may be solid in construction, perforated, or some combination to allow or restrict the movement of air into the spaces the floor panels contain. Floor panels may be used in any combination to accomplish a wide variety of air movement patterns based on the application. Embodiments of this disclosure contemplate the use of the rack floor panel 130 and aisle floor panel 140 as part of an air containment and direction method.

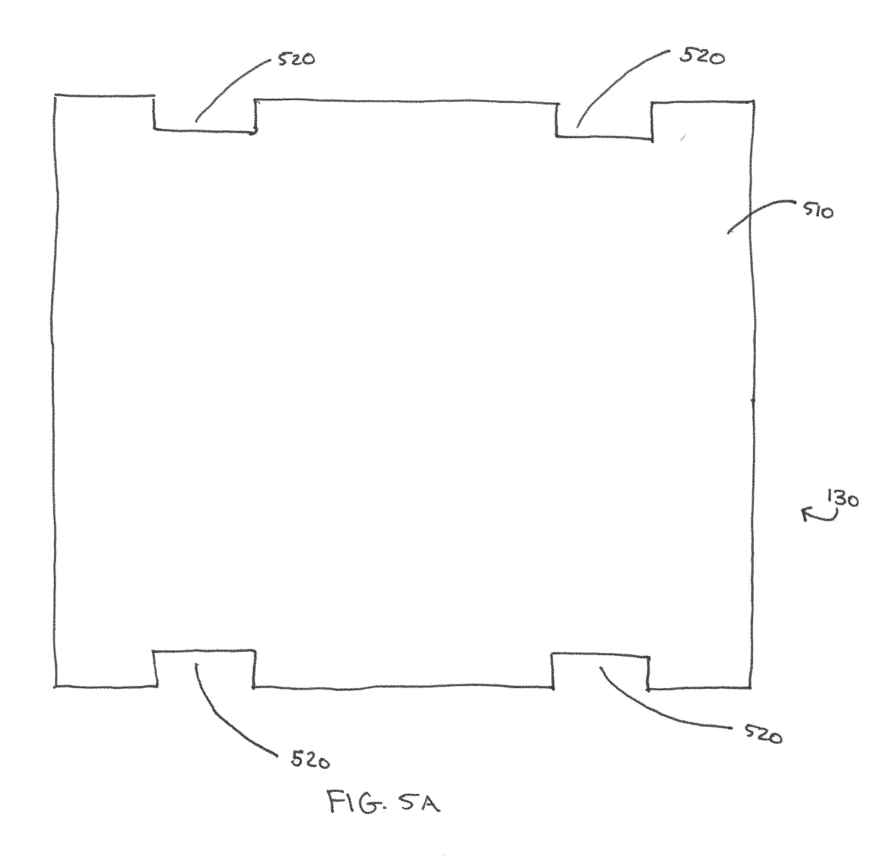

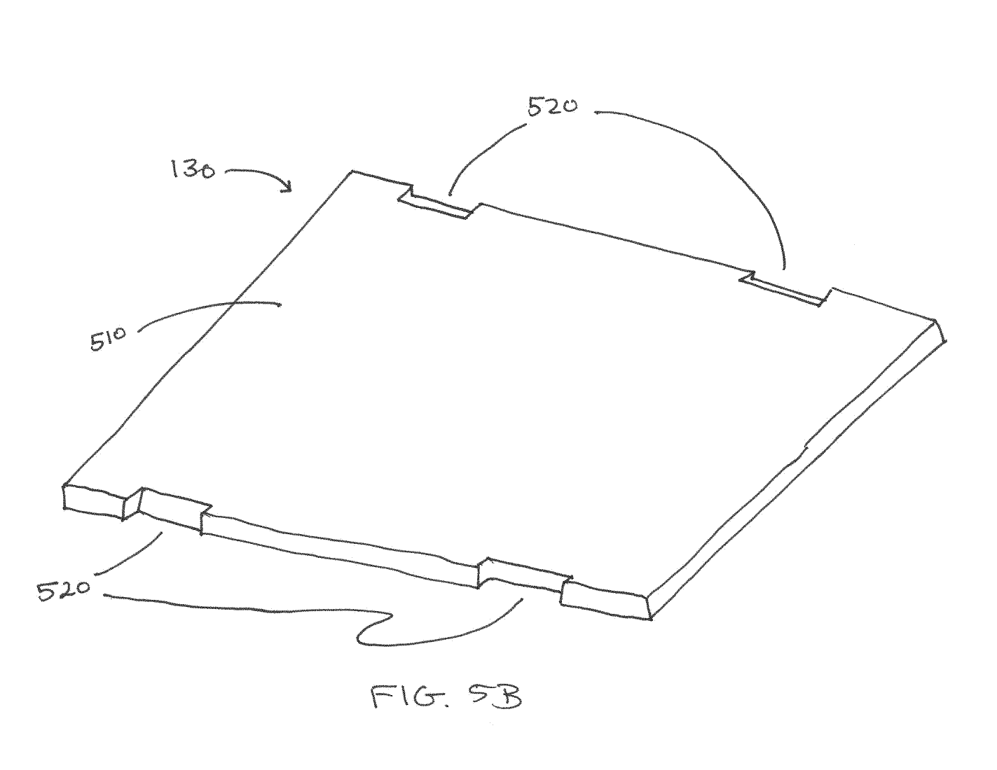

FIG. 6A illustrates a perspective view of an alternate embodiment for supporting and stabilizing an equipment rack in accordance with various embodiments of this disclosure. In this embodiment, one or more channel spacers 120 are placed on a floor. One or more retention brackets 110 are placed on the lower tier 420 (FIG. 4) of the channel spacers 120, and the rack floor panel 130 is operatively connected by placing the rack floor panel 130 between the one or more channel spacers 120. One or more aisle floor panels 140 are placed adjacent to each rack floor panel 130 to form a planar surface where the equipment rack is operatively connected between the retention brackets. Each retention bracket 110 is operatively connected to the equipment rack (e.g., equipment rack 100) utilizing fastening hardware placed through the disposed opening 320 on the vertical plate of the retention bracket 110.

FIG. 6B illustrates a perspective view of an alternate embodiment for supporting and stabilizing an equipment rack in accordance with various embodiments of this disclosure. One or more retention brackets 110 each having the vertical plate 350 and the horizontal plate consisting of the top horizontal plate 380, the bottom horizontal plate 390, and the horizontal plate slot 370 are utilized. As one of many examples, the horizontal plate of the retention bracket 110 is inserted into a channel slot 610 in the floor as far as the horizontal plate slot 370. Once at that depth, the entire retention bracket 110 is rotated such that the horizontal plate slot 570 operatively connects to the floor where the top horizontal plate 580 operatively connects to the top of the floor and the bottom horizontal plate 390 operative connects to the bottom of the floor. It should be appreciated that several embodiments allow for varying degrees of rotation. In this way, the vertical plate 350 may be oriented to accommodate various equipment rack 100 configurations. Each retention bracket 110 is operatively connected to the equipment rack (e.g., equipment rack 100) utilizing fastening hardware placed through the disposed opening 320 on the vertical plate of the retention bracket 110.

It should be appreciated embodiments of this disclosure contemplate various configurations of retention brackets 110, channel spacers 120, rack floor panels 130, and aisle floor panels 140 in a variety of configurations to accommodate the variety of configurations contemplated by a user.

FIG. 7 illustrates an exploded perspective view of an alternate embodiment for supporting and stabilizing an equipment rack in accordance with various embodiments of this disclosure. This disclosure contemplates various methods for installing an equipment rack support and stabilization system. For example, one preferred embodiment of the method includes installing the channel spacers 120 on a floor, with each channel spacer 120 having the upper tier 430 and the lower tier 420. The method further includes installing the horizontal plates of the retention brackets 110 to the lower tiers of the channel spacers 120. The method further includes installing the rack floor panels 130 between the channel spacers 120, such that the retention slots 200 are aligned with the vertical plates 350 of the plurality of retention brackets. The method further includes installing the aisle floor panels 140, with the bottoms of the aisle floor panels operatively connected to the upper tiers of the channel spacers and the horizontal plates of the plurality of retention brackets. The method further includes installing an equipment rack, such as equipment rack 100, supported by the tops of the rack floor panels 130 and the vertical plates of the plurality of retention brackets 110.

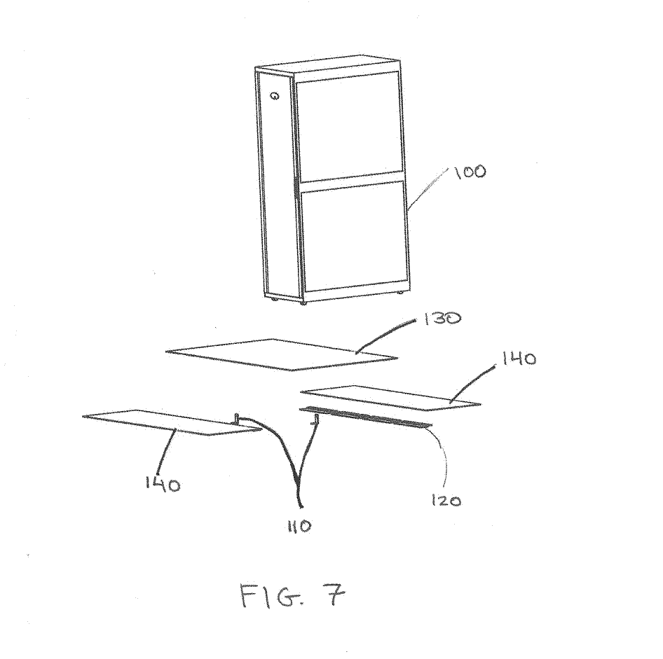

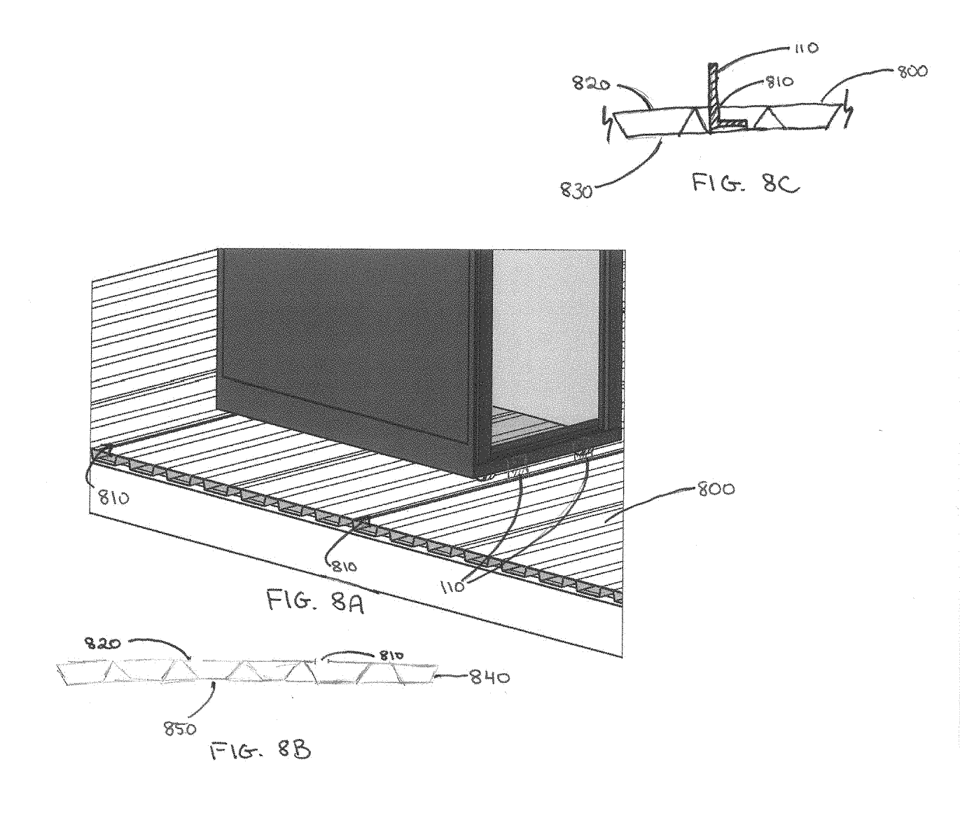

Alternate embodiments are contemplated which do not require operatively connecting components by stacking them from nearest to the sub-floor to furthest from the sub-floor. In these cases, methods of assembly contemplate the insertion of retention brackets 110 from either end of the rack floor panels 130 and aisle floor panels 140. Alternatively, in cases where a combined floor panel is in use, as detailed in FIG. 8A, methods of assembly contemplate the insertion of retention brackets 110 from either end of the combined floor panel.

FIG. 8A illustrates an alternate embodiment of a combined floor panel 800, which is configured to function both as a rack floor panel and aisle floor panel as detailed above, for supporting and stabilizing an equipment rack 100 in accordance with various embodiments of this disclosure. One of many such stabilization methods for the equipment rack 100 are one or more retention brackets 110 operatively connected to the equipment rack 100 and a retention bracket channel 810. FIG. 8B is a cross sectional view of FIG. 8A.

Each combined floor panel 800 contains a retention bracket channel 810 configured to accommodate one or more retention brackets 110 to secure the equipment rack 100. Various embodiments include a combined floor panel top 820, a combined floor panel bottom 830, and combined floor panel support 840. It should be appreciated that while a truss mechanical support is illustrated, any adequate support structure may be used, such as, but not limited to, columns or joists between the combined floor panel top 820 and bottom 830. Each combined floor panel 800 may be a single piece of material or multiple pieces of material formed to fit any appropriate size for an application.

FIG. 8C illustrates a cross sectional view of an alternate embodiment of the combined floor panel of FIG. 8B. In this embodiment a retention bracket 110 is operatively connected to the retention bracket channel 810 within the combined floor panel 800 and is configured to stabilize or otherwise anchor an equipment rack 100.

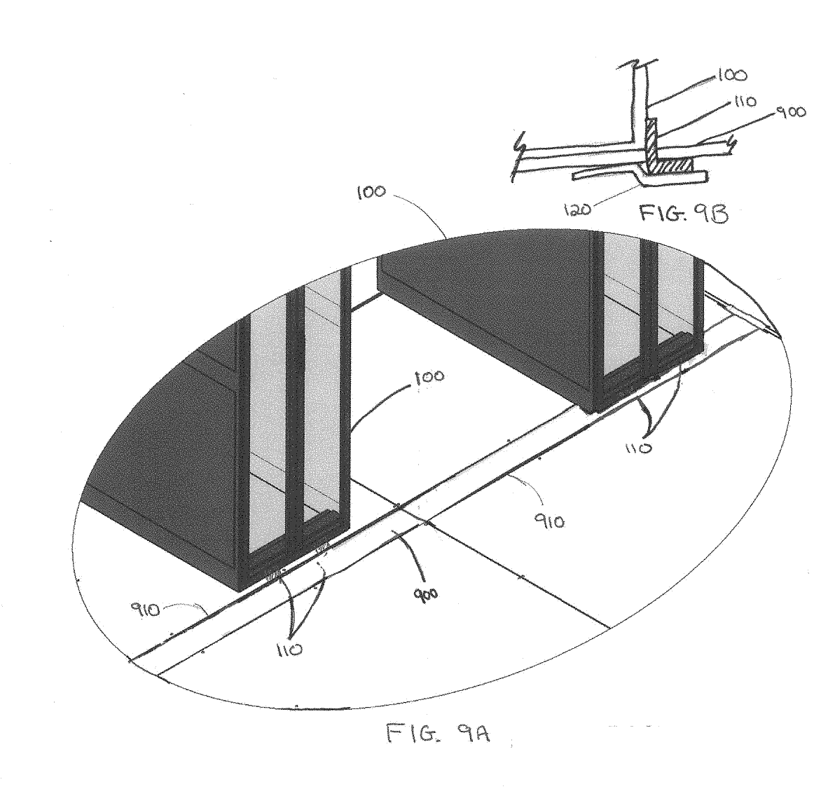

FIG. 9A illustrates a perspective view of an alternate embodiment of a rack floor panel adaptor 900 for supporting and stabilizing an equipment rack 100 in accordance with various embodiments of this disclosure. The rack floor panel adaptor 900 may be rotated in 180 degrees in either horizontal direction to allow a rack floor panel adaptor channel 910 to align with the equipment rack 100. Retention brackets 110 are placed within the rack floor panel adaptor channel 910 to accommodate multiple equipment rack 100 depths. As illustrated in FIG. 9A, both a smaller and larger depth equipment rack 100 may be accommodated with a single rack floor panel adaptor 900. The rack floor panel adaptor 900 is configured to self-align, utilizing mounting holes disposed within the rack floor panel adaptor 900. It should be appreciated the rack floor panel adaptor 900 length may be various and/or adjustable to accommodate various equipment rack 100 depths.

FIG. 9B illustrates a cross sectional view of alternate embodiment of the rack floor panel adaptor illustrated in FIG. 9A. As one of many examples of this embodiment, the retention brackets 110 are operatively connected within the rack floor panel adaptor channel 910 of the rack floor panel adaptor 900. The retention brackets 110 are operatively connected by the lower tiers 410 of the channel spacers 120. An equipment rack 100 is operatively connected to the retention bracket 110.

At least some embodiments of the equipment rack support and stabilization systems described herein may be provided as a kit to be assembled and installed by the end user. Such a kit may be configured to include a plurality of retention brackets 110, each retention bracket having the vertical plate 300, 340 and the horizontal plate 310, 330. One or more openings 320 are formed in the vertical plate 330, 340, 350 of the retention bracket 110 to secure to the equipment rack 100. The kit further includes a plurality of channel spacers 120, each channel spacer having the lower tier 410, the upper tier 420, and the tier interconnect 430. The lower tiers 410 of the channel spacers 120 operatively connect and support the horizontal plates 310, 330, 380, 390 of the retention brackets 110. Also, the kit includes a plurality of rack floor panels 130 having the top 510, the bottom, and the plurality of retention slots 520. The tops 510 of the plurality of rack floor panels 130 supports the equipment rack 110 and the horizontal plates 310, 330 of the retention brackets 110 fit within the plurality of retention slots 520.

Alternate embodiments of embodiments of a kit may include one or more rack base mounting plates to secure the equipment rack 100 and the vertical plate of the plurality of retention brackets. Further embodiments of the kit may include a plurality of aisle floor panels 140 connected to and supported by the upper tier 420 of the plurality of channel spacers 120.

Equipment rack support and stabilization systems disclosed herein simplify the design, maintenance, and/or configuration of new or existing data center buildings, containers, or enclosures and eliminate or reduce a reliance on the structure of a building to support the electronic equipment. Further, such systems enable the reduction of structures such as racks and rack equipment that may not be originally designed for data center use, or to save a data center business, time and money in building or outfitting a data center. At least some rack support and stabilization systems disclosed herein may be assembled with a minimal number of tools, or no tools, by a minimum number of personnel.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

1. A support and stabilization system for an equipment rack, the system comprising:
a plurality of retention brackets, each retention bracket having a first plate and a second plate extending from the first plate, the first plate having one or more openings formed therein;
a plurality of channel spacers, each channel spacer having a lower tier, an upper tier, and a tier interconnect, the lower tier of the channel spacer being configured to connect and support the second plate of the retention bracket;
a plurality of rack floor panels, each rack floor panel having a top, a bottom, and a plurality of retention slots, the top of each rack floor panel being configured to support the equipment rack, and the second plate of the retention bracket being configured to fit within a retention slot of the plurality of retention slots; and
a plurality of aisle floor panels connected to and supported by the upper tiers of the plurality of channel spacers.

2. The system of claim 1, wherein the second plate includes a top second plate, a bottom second plate, and a second plate slot positioned between the top horizontal plate and the bottom horizontal plate, the first plate is configured approximately perpendicular to the second plate and rotated approximately perpendicular on a horizontal axis, the top second plate being operatively connected on one side of a bottom of the first plate.

3. The system of claim 1, wherein an opening of the one or more openings disposed within the first plate of each retention bracket is configured to receive a fastener to releasably secure the equipment rack to the retention bracket.

4. The system of claim 1, further comprising a rack base mounting plate to secure the equipment rack to the first plate of each retention bracket.

5. The system of claim 3, wherein the rack base mounting plate includes one or more openings formed therein and configured to receive a fastener to releasably secure the equipment rack.

6. The system of claim 1, wherein the first plate of each retention bracket is configured to extend and retract to achieve a height.

7. The system of claim 1, wherein the second plate of each retention bracket is configured to extend and retract to achieve a depth.

8. The system of claim 1, wherein the rack floor panel is perforated to allow airflow between the top and the bottom of the rack floor panel.

9. The system of claim 1, wherein the aisle floor panel is perforated to allow airflow between the top and the bottom of the aisle floor panel.

10. The system of claim 1, wherein the rack floor panel contains an integrated channel spacer and retention bracket.

11. A kit for a rack support and stabilization system, including:
a plurality of retention brackets, each retention bracket having a first plate and a second plate extending from the first plate, the first plate having one or more openings formed therein to secure to an equipment rack;
a plurality of channel spacers, each channel spacer having a lower tier, an upper tier, and a tier interconnect, the lower tier of the channel spacer being configured to connect and support the second plate of the retention bracket;
a plurality of rack floor panels, each rack floor panel having a top, a bottom, and a plurality of retention slots, the top of each rack floor panel being configured to support the equipment rack, and the second plate of the retention bracket being configured to fit within a retention slot of the plurality of retention slots; and
a plurality of aisle floor panels connected to and supported by the upper tiers of the plurality of channel spacers.

12. The kit of claim 10, wherein the kit includes a rack base mounting plate to secure the equipment rack to the first plate of each retention bracket.

13. The kit of claim 11, wherein the kit includes a plurality of aisle floor panels connected to and supported by the upper tiers of the plurality of channel spacers.

14. A method for installing an equipment rack support and stabilization system, including:
a plurality of channel spacers, each channel spacer having a lower tier, an upper tier, and a tier interconnect, the lower tier of the channel spacer being configured to connect and support the second plate of the retention bracket;
installing a second plate of a plurality of retention brackets, each retention bracket having a first plate and a second plate extending from the first plate, the first plate having one or more openings formed therein to secure to an equipment rack;
installing a plurality of rack floor panels, each rack floor panel having a top, a bottom, and a plurality of retention slots, the top of each rack floor panel being configured to support the equipment rack, and the second plate of the retention bracket being configured to fit within a retention slot of the plurality of retention slots;
installing a plurality of aisle floor panels connected to and supported by the upper tiers of the plurality of channel spacers; and
installing an equipment rack supported by the top of the plurality of rack floor panels and the first plate of the plurality of retention brackets.
